(19) United States
(12) Patent Application Publication
(10) Pub. No.: US 2026/0190247 A1
(43) Pub. Date: Jul. 2, 2026

(54) METHOD FOR APPLYING A PROTECTIVE LAYER TO A CIRCUIT-BOARD ASSEMBLY

(71) Applicant: Brose Fahrzeugteile SE & Co. Kommanditgesellschaft, Würzburg, Würzburg (DE)

(72) Inventor: Giulia WENDELIN, Bamberg (DE)

(21) Appl. No.: 18/862,637

(22) PCT Filed: Apr. 24, 2023
(86) PCT No.: PCT/EP2023/060582

§ 371 Date: Dec. 17, 2024

(30) Foreign Application Priority Data
May 3, 2022 (DE) 10 2022 204 366.9

(51) Int. Cl. H05K 3/28; H05K 1/181

(52) U.S. Cl. CPC H05K 3/284; H05K 1/181; H05K 2201/0989; H05K 2201/10522; H05K 2203/0104

(57) ABSTRACT

A method for applying a protective layer to a circuit-board assembly. The circuit-board assembly has at least one protective-layer area on which the protective layer is to be applied, and at least one free area, arranged outside the protective-layer area. In a first method step, a specified amount of the protective layer is applied in the free area. In a subsequent, second method step, the protective layer is applied to the protective-layer area.

The invention relates to a method for applying a protective layer to a circuit-board assembly, wherein the circuit-board assembly has at least one protective-layer area on which the protective layer is to be applied. The invention further relates to a coating device for carrying out the method and to a circuit-board assembly.

In a modern motor vehicle, electric motors are used in multifarious ways as drives for different actuating elements. Electric motors are used, for example, as window-lift, sliding-roof or seat-adjustment drives, as steering drives (EPS, electrical power steering), as radiator fan drives or as transmission actuators. Such electric motors must have a relatively high torque or power density and be operationally reliable even at high temperatures.

In a brushless electric motor, the alternating current provided for feeding the stator winding is usually generated by a converter (inverter). In relatively small electric motors, this converter is frequently accommodated together with associated control electronics in an electronics compartment, which is integrated in the motor housing. The (control) electronics have to be protected against moisture, for which reason in such electric motors, for example used as coolant compressors in motor vehicles, comparatively high requirements are placed on the tightness of the electronics compartment.

By means of coating devices, protective layers can additionally be applied to the electronics or to a circuit-board assembly, for example to a circuit board (board, circuit carrier) and/or to an electronic component arranged thereon.

Such protective layers are implemented in particular as thermal and/or electric insulation layers, in order to protect the circuit board or the components from external influences. Such protective layers are usually applied as a liquid (protective) varnish or as a liquid potting compound, the protective layer then being cured.

In addition to the coating of the entire circuit-board assembly, coating of subregions or individual electronic components on the circuit board may also be desired. Because of high precision and reproducibility, as a rule a mechanical or robot-assisted application by means of a suitable metering head for spraying the protective layers to the subregions of the circuit board that are to be coated is used here. For example, use is made of an applicator having a varnishing needle for applying or spraying on the protective coating or the protective varnish.

At the start of such a coating or varnishing process, air is often located in the varnishing needle of the applicator. At the start of the coating process, this air is applied to the electronic components located in the area to be coated and ultimately leads to air bubbles (gas bubbles) in the protective coating, which can also be present after the curing of the protective coating. In particular in applications in the high voltage range (greater than 60 V, for example 470 V or 810 V), such air bubbles represent a safety-critical problem, since they have a detrimental influence on the electric insulation capacity of the coated areas.

To avoid this air bubble problem, it is possible, for example, to optimize the coating or varnishing process and/or the coating device used for this purpose until no more air bubbles are drawn into the varnishing needle. Disadvantageously, such optimization necessitates a great deal of outlay on time and costs, in addition a certain susceptibility to faults arising as a result of changing the coating material, operator, applicator or the like.

The invention is based on the object of specifying a particularly suitable method for applying a protective layer to a circuit-board assembly. In particular, it is intended to be ensured in a simple and reliable way that no air bubbles occur in the protective layer that is applied in an area of the circuit-board assembly that is to be protected. The invention is further based on the object of specifying a particularly suitable coating device and a particularly suitable circuit-board assembly.

With regard to the method, according to the invention the object is achieved by the features of claim 1 and with regard to the coating device, by the features of claim 4, and with regard to the circuit-board assembly, by the features of claim 5. Advantageous embodiments and developments are the subject matter of the sub-claims. The advantages and embodiments listed with regard to the method can be transferred analogously also to the coating device and/or the circuit-board assembly and vice versa.

The conjunction “and/or” is to be understood here and below in such a way that the features linked by means of this conjunction can be implemented both together and also as alternatives to one another.

If method steps are described below, advantageous embodiments for the coating device result in particular from the fact that this is designed to carry out one or more of these method steps.

The method according to the invention is provided for applying a protective layer to a circuit-board assembly and is suitable and configured for this purpose. “Applying a protective layer” is to be understood in particular to be the depositon or application of a protective layer, that is to say a coating or varnishing process. The method is therefore in particular a coating or varnishing method.

A “protective layer” is to be understood in particular to be an electric and/or thermal insulation layer which, for example, is applied to the circuit-board assembly as a liquid (protective) varnish or as a liquid potting compound and is then cured. The protective layer or the protective layer material (varnish, potting compound) is, for example, applied by means of a movable applicator. The applicator has a nozzle or a varnishing needle from outlet opening for the protective layer. The protective layer can be applied to the circuit-board assembly by means of the applicator, for example by means of spraying, dispensing, jetting or film-coating.

A “circuit-board assembly” is to be understood here and below in particular to be a circuit board (printed circuit board) or flat subassembly or punched grid, in particular an overmolded punched grid, as a circuit carrier, which is populated with at least one electronic component. The method is carried out in particular in the course of circuit-board population or circuit-board production (printed circuit board assembly, PCBA). The circuit-board assembly is, for example, part of the electronics of an electric-motor drive, in particular an electric-motor refrigerant compressor.

The circuit-board assembly has at least one protective-layer area and at least one free area arranged outside the protective-layer area.

A “protective-layer area” is to be understood here and below in particular to be a (sub)area or an area of the circuit-board assembly on which a protective layer is to be applied for the purpose of thermal and/or electrical insulation (varnish area). A protective-layer area is therefore a region of the circuit-board assembly on which a protective layer is necessary or desired for design or wiring reasons. In other words, the protective-layer area is an area of the circuit-board assembly which is critical with respect to the insulation and which is intended to be protected or insulated with the protective layer to be applied.

A “free area” is to be understood here and below in particular to be a (sub)area or an area of the circuit-board assembly which is not critical with respect to the insulation. In other words, a free area is an area of the circuit-board assembly on which the application of a protective layer substantially has neither positive nor negative effects on the function of the circuit-board assembly or the components of the latter. An application or applying of the protective layer is therefore not relevant in the free area. The free area can be a free area on a circuit board. Alternatively, one or more electronic components may also be arranged in the free area. Here, a free area is to be distinguished from a so-called “restricted area” of the circuit-board assembly, on which no protective layer may be applied, since this otherwise has a detrimental effect on the function of the circuit-board assembly. In other words, the free area is located outside the protective-layer area and outside restricted areas of the circuit-board assembly which are possibly present.

According to the method, in a first method step a predefined amount of the protective layer, that is to say the protective layer or varnishing material, is applied in the free area. This can be implemented, for example, by the application of a predefined volume or by the application for a predefined time period. The predefined amount is chosen such that following the application of the predefined amount, there is a sufficiently low probability of air bubbles occurring in a subsequently applied protective layer. What probability is considered as sufficient and how small the probability is in practical terms is initially unimportant. This can be determined, for example, from preceding coating data or from corresponding trials or experiments. For different protective-layer materials, operating and environmental conditions or application scenarios, the result under certain circumstances is different predefined amounts which are applied in the free area.

In a subsequent second method step, the protective layer is applied to the protective-layer area. The predefined amount in the first method step is preferably always lower than the amount of the protective layer that is applied in the protective-layer area. As a result, a particularly suitable method for applying a protective layer to a circuit-board assembly is realized.

According to the invention, to avoid air and gas bubbles in the relevant varnish area (protective-layer area), the starting point of the varnishing, i.e. of the coating process, is thus placed in an adjacent area (free area), which is not critical with respect to the insulation. The free area is thus, for example, designed as a starting area for the varnishing or coating process (varnish application starting area, LASF). This area additionally lies outside the restricted area, in which no varnish may reach. According to the invention, before the actual varnishing or coating operation, a defined amount of varnish is applied in the free area or the LASF. This amount is preferably many times smaller than the amount applied in the varnish area. As a result, the air inside the applicator is removed during the application in the free area, so that there is no air in the applicator during the subsequent application in the protective-layer area. As a result, substantially no air bubbles are applied in the relevant protective-layer area. As a result, process development time is saved and the susceptibility to faults is reduced, which leads to a reduction in scrap costs.

The application or applying of the protective layer can be carried out here, for example, as so-called “conformal coating”, in which an overall protective layer is applied with a uniform layer thickness, for example by casting, spraying or film-coating. In the varnish area, air bubbles which, for example, occur under the components or are included during the application can occur individually. These air bubbles are relatively small as a rule, however, and not critical. In particular, the air bubbles do not occur in the size and amount as in the LASF.

Alternatively, the application or applying of the protective layer can also be carried out, for example, in a “dam and fill” method. Here, individual areas on the circuit-board assembly are potted or coated without impairing the surrounding areas and components. For this purpose, in the method also designated as “frame and fill”, two potting media or protective-layer materials with a different viscosity are used. In a first step, a dam or frame of higher-viscosity material is metered around the area on the circuit-board assembly that is to be protected. The “trough” which thus arises is then filled, for example, with a liquid potting resin as a protective layer, until the protective-layer area is completely covered. According to the invention, the varnishing in each case begins in a non-critical part within the dam (free area), so that no more bubbles are applied until the area that is critical in terms of insulation (protective-layer area) is reached. The dam is therefore in particular applied in such a way that it encloses both the protective area and the free area.

In an advantageous embodiment, the free area is arranged beside or adjacent to the protective-layer area. For example, the free area is chosen or placed such that it adjoins the protective-layer area, in particularly adjoins the latter directly.

In an expedient development, the second method step follows the first method step without any interruption or pause. The second method step is therefore carried out after the first method step without any interruption. The transition between the free area and protective-layer area, that is to say the LASF and varnish area, is thus made without any interruption of the varnishing or of the coating process. This ensures that no new air can get into the applicator between the first and second method steps.

The first varnish area (protective-layer area) is preferably chosen such that sufficient space for the LASF (free area) is available directly adjacent thereto. The varnish application is started in this LASF and merges without interruption into the varnish area. The air that is still in the applicator is therefore applied in the LASF, and the varnish area defined by the insulation coordination is applied substantially without bubbles.

The coating device according to the invention is provided to apply or deposit a protective layer to a circuit-board assembly and is suitable and configured for this purpose. The coating device has a movable applicator and a protective-layer reservoir coupled thereto. The applicator is movable, for example, by means of a robot, and can thus be moved to different positions on the circuit-board assembly. Liquid protective-layer material is accommodated in the protective-layer reservoir, wherein the applicator conveys protective-layer material out of the protective-layer reservoir and applies it to the circuit-board assembly. The applicator is coupled using signals to a controller (that is to say a control unit).

In general, the controller is designed—in terms of programming and/or circuitry—to carry out the above-described method according to the invention. In practical terms, the controller is thus designed to move the applicator to a free area and to activate and/or control the applicator in such a way that a predefined amount of protective-layer material from the protective-layer reservoir is applied to the free area. The controller is further designed to then move the applicator to the protective-layer area and to apply a protective layer there.

In a preferred configuration, the controller is, at least at the core, formed by a microcontroller having a processor and a data memory, in which the functionality for carrying out the method according to the invention is implemented by programming in the form of operating software (firmware) so that the method—if appropriate in interaction with a device user—is carried out automatically as the operating software is executed in the microcontroller. Within the context of the invention, the controller can, however, alternatively also be formed by a non-programmable electronic component, such as, for example, an application-specific integrated circuit (ASIC) or by an FPGA (field-programmable gate array), in which the functionality for carrying out the method according to the invention is implemented by circuitry means.

The circuit-board assembly according to the invention is provided for electronics of an electric refrigerant drive and is suitable and configured for this purpose. The circuit-board assembly has at least one protective-layer area and at least one free area, a protective layer being applied in the protective-layer area and the free area. The protective layer is applied by an above-described method according to the invention. The protective layer can have air bubbles in the free area but is substantially bubble-free in the protective-layer area.

Exemplary embodiments of the invention are explained in more detail below with reference to a drawing, in which:

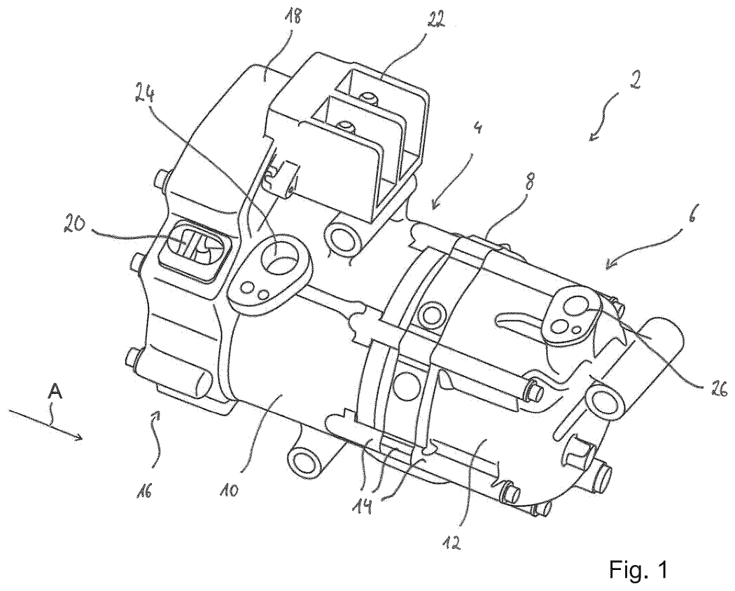

FIG. 1 shows a perspective view of an electric refrigerant compressor having electronics,

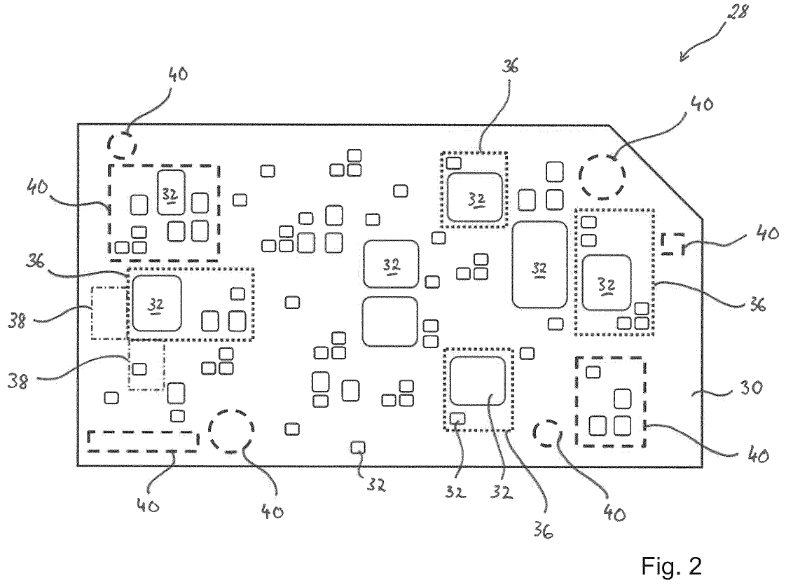

FIG. 2 shows a schematic illustration of a circuit-board assembly of the electronics, with a populated circuit board,

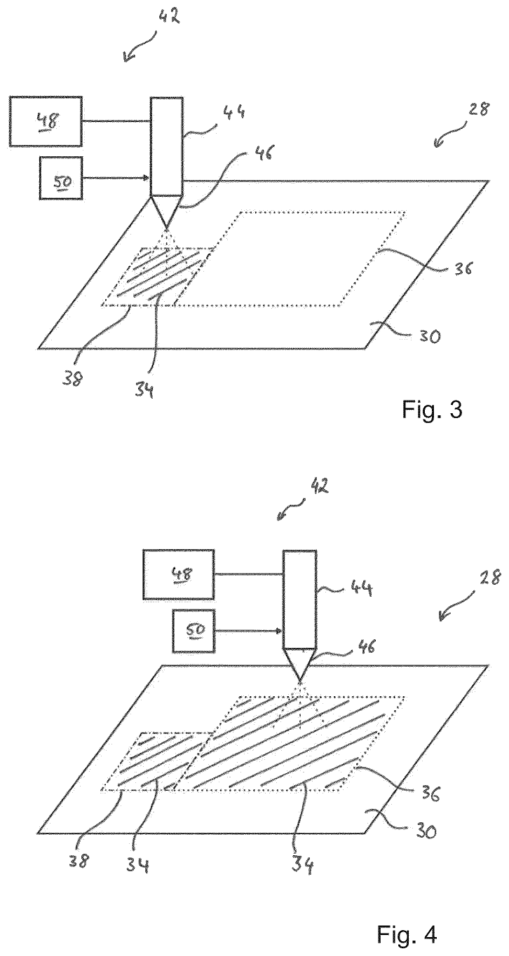

FIG. 3 shows a schematic illustration of a coating process of a free area on the circuit board, and

FIG. 4 shows a schematic illustration of a coating process of a protective area on the circuit board.

Mutually corresponding parts and sizes are always provided with the same designations in all the figures.

FIG. 1 shows an electric or electric-motor refrigerant compressor 2 which, for example, is installed in a refrigerant circuit, not specifically illustrated, of an air-conditioning system of a motor vehicle. The refrigerant compressor 2 which, for example, is of modular design, has an electric (electric-motor) drive (drive module) 4 and a compressor head (compressor module) 6 coupled thereto. Provided between the drive 4 and the compressor head 6 is an A-side bearing shield (center plate) 8 as a mechanical interface, by means of which the compressor head 6 is connected to the drive 4 in drive terms.

The bearing shield 8 forms an intermediate wall between a drive housing 10 and a compressor housing 12. The compressor head 6 is connected to the drive 4 (joined, screwed) by means of circumferentially distributed flange connections 14 extending in an axial direction A of the refrigerant compressor 2 which, in the figures, are provided with designations merely by way of example.

A housing sub-region of the drive housing 10 on the compressor side is designed as a motor housing to receive an electric motor and is separated in fluid and pressure terms by an integrated housing intermediate wall, not shown, from an electronics unit 16 integrated in the drive housing 10. The electronics unit 16 has an electronics housing 18 provided with a housing cover, wherein a housing base of the approximately pot-shaped electronics housing 18 is formed by the housing intermediate wall. Motor electronics (electronics) 20 activating the electric motor are accommodated in the electronics housing 18.

The drive housing 10 has a connection section 22 in the area of the electronics housing 18 to make electrical contact between the electronics 20 and a vehicle electrical system of the motor vehicle.

The refrigerant compressor 2 has a (refrigerant) inlet or (refrigerant) feed 24 for connection to the refrigerant circuit, and a (refrigerant) outlet 26. The inlet 24 is molded on in an area of the drive housing 10 that faces the electronics housing 18. The outlet 26 is molded on to a base of a compressor housing 12. In the connected state, the inlet 24 forms the low-pressure or suction side (suction-gas side), and the outlet 26 forms the high-pressure or pump side (pumping side) of the refrigerant compressor 2.

The electronics 20 have a circuit-board assembly 28 illustrated schematically in FIG. 2. The circuit-board assembly 28 has a circuit board 30 which is populated with a number of electronic components 32. The components 32 are provided with designations in FIG. 2 merely by way of example.

To protect sensitive components 32, the circuit-board assembly 28 is provided in some areas with a thermally and/or electrically insulating protective layer 34, in particular a protective varnish. In other words, the circuit-board assembly 28 is coated or varnished with a protective layer 34 in some areas.

Different (sub)areas 36, 38, 40 are formed on the circuit-board assembly 28. In the following, the areas 36 are also designated as protective-layer areas, the areas 38 being designated as free areas and the areas 40 being designated as restricted areas.

A protective layer 34 is applied in each of the protective-layer areas 36 illustrated dotted. The protective-layer areas 36 are critical areas of the circuit-board assembly 28 with respect to the insulation. This means that the protective layer 34 in the protective-layer areas 36 ensures reliable and operationally secure operation of the electronics or of the circuit-board assembly 28.

A protective layer 34 is likewise applied in each of the free areas 38 illustrated dash-dotted. The free areas 38 are non-critical areas of the circuit-board assembly 28 with respect to the insulation. This means that the protective layer 34 in the free areas 38 substantially has no influence on the operation of the electronics or the circuit-board assembly 28.

No protective layer 34 is applied in the restricted areas 40 illustrated dashed. he restricted areas 40 are areas of the circuit-board assembly 28 in which a protective layer 34 would have a detrimental influence on the operation of the electronics or the circular-board assembly 28. In other words, the restricted areas 40 are free of a protective layer 34 for the purpose of thermal and/or electrical conductivity. Restricted areas 40 can also be, for example, support points for the assembly, holes for the screw connections, barcodes or the like.

The circuit-board assembly 28 in this exemplary embodiment has, by way of example, four rectangular protective-layer areas 36, in which electronic components 32 are arranged. At least one free area 38 adjoins each of the protective-layer areas 36 directly, wherein in FIG. 2 only two rectangular free areas 38 are shown for one of the protective-layer areas 26. Components 32 can be arranged in the free area 38; alternatively, the free area 38 can also be a free area on the circuit board 40. FIG. 2 shows both a free area 38 with components 32 and also a free area 38 without. Preferably, however, only one free area 38 is provided for each protective-layer area 36. FIG. 2 also has eight restricted areas 40 which, for example, are of rectangular or circular design.

The protective layer 34 can have air bubbles included in the free areas 38, the protective layer 34 being of substantially bubble-free design in the protective-layer areas 36.

By using FIGS. 3 and 4, a coating method according to the invention, i.e. a method for applying the protective layer 40 to the circuit-board assembly 28, is explained in more detail below.

The coating method is carried out by means of a coating device 42. The coating device 42, also designated as a varnishing system below, has a movable applicator 44 with a varnishing needle 46, which is connected to a protective-layer reservoir 48. The applicator 44 is coupled to a controller 50, which controls and/or regulates the coating method.

According to the method, the applicator 44 is firstly moved into a free area 38, and a predefined amount of the liquid protective-layer material or varnish material from the protective-layer reservoir 48 is applied (FIG. 3); it is applied as a protective layer 34. The applicator 44 is then moved to the respectively directly adjacent protective-layer area 36 and coated with the protective layer 34.

The method takes account of the fact that at the start of a coating or varnishing process, there is frequently air in the varnishing needle 46 of the applicator 44, which can lead to formation of air bubbles in the applied protective layer 34. According to the method, to avoid air and gas bubbles in the relevant varnish area (protective-layer area 36), the starting point of the varnishing is placed in a free area 38 directly adjacent to the varnish area 36. The free area 38 is thus designed as a starting area for the varnishing or coating process (varnish application starting area, LASF).

The varnish application or the coating method is started in this LASF 38 and merges without interruption into the varnish area 40. Before the actual varnishing or coating process of the varnish area 40, a defined amount of varnish is applied in the free area 38 or the LASF. This amount is preferably many times smaller than the amount applied in the varnish area 36. The predefined amount is chosen in such a way that the air present in the varnishing needle 46 is completely conveyed to the outside so that, for the coating process of the varnish area 40, it is ensured that there is no air in the varnishing needle 46. As a result, the application of a substantially bubble-free protective layer 34 to the varnish area 40 is ensured.

The applied protective layer 34 is preferably cured at the end of the coating process.

The claimed invention is not restricted to the exemplary embodiments described above. Instead, other variants of the invention can also be derived therefrom by a person skilled in the art within the context of the disclosed claims, without departing from the subject matter of the claimed invention. In particular, all the individual features described in connection with the various exemplary embodiments can also be combined in any other way within the context of the disclosed claims without departing from the subject matter of the claimed invention.

### LIST OF DESIGNATIONS

2 Refrigerant compressor
4 Drive
6 Compressor head
8 Bearing shield
10 Drive housing
12 Compressor housing
14 Flange connection
16 Electronics unit
18 Electronics housing
20 Electronics
22 Connection section
24 Inlet
26 Outlet
28 Circuit-board assembly
30 Circuit board
32 Component
34 Protective layer
36 Protective-layer area/varnish area
38 Free area/varnish application starting area
40 Restricted area
42 Coating device
44 Applicator
46 Varnishing needle
48 Protective-layer reservoir
50 Controller
A Axial direction

1-5. (canceled)

6. A method for applying a protective layer to a circuit-board assembly, the method comprising:
providing the circuit-board assembly with at least one protective-layer area, on which the protective layer is to be applied, and at least one free area arranged outside the protective-layer area;
in a first method step, applying a specified amount of the protective layer in the at least one free area; and
in a subsequent, second method step, applying the protective layer (34) to the protective-layer area.

7. The method according to claim 6, wherein the at least one free area is arranged adjacent the protective-layer area.

8. The method according to claim 6, which comprises carrying out the second method step following the first method step without interruption therebetween.

9. A coating device for applying a protective layer to a circuit-board assembly, the coating device comprising:
a movable applicator and a protective-layer reservoir coupled to said movable applicator; and
a controller for carrying out the method according to claim 6.

10. A circuit-board assembly carrying electronics of an electric refrigerant drive, the circuit board assembly comprising:
at least one protective-layer area and at least one free area;
and a protective layer applied in said protective-layer area and in said free area.
